(19) United States
(12) Patent Application Publication
(10) Pub. No.: US 2008/0136040 A1
(43) Pub. Date: Jun. 12, 2008

(54) Methods of Forming Electrical Interconnects Using Non-Uniformly Nitrified Metal Layers and Interconnects Formed Thereby

(75) Inventors: Jin-Ho Park, Gyeonggi-do (KR); Seong-Hwee Cheong, Seoul (KR); Gil-Heyun Choi, Seoul (KR); Sang-Woo Lee, Seoul (KR); Ho-Ki Lee, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/778,344

(22) Filed: Jul. 16, 2007

(30) Foreign Application Priority Data
Dec. 11, 2006 (KR) 2006-125310

(51) Int. Cl. H01L 21/4763; H01L 23/48

(52) U.S. Cl. 257/774; 438/631; 257/E23.01; 257/E21.495

(57) ABSTRACT

Methods of forming electrical interconnects include forming a first electrically insulating layer on a semiconductor substrate and then forming an opening in the first electrically insulating layer. A step is performed to line a sidewall of the opening with a nitrified first metal layer having a non-uniform nitrogen concentration therein. An electrically conductive pattern is formed in the opening. A second metal nitride layer is provided between the electrically conductive pattern and the nitrified first metal layer.

### REFERENCE TO PRIORITY APPLICATION

This application claims priority under 35 USC § 119 to Korean Application Serial No. 2006-125310, filed Dec. 11, 2006, the disclosure of which is hereby incorporated herein by reference.

### FIELD OF THE INVENTION

The present invention relates to methods of forming integrated circuit devices and, more particularly, to methods of forming integrated circuit devices having electrical interconnects therein.

### BACKGROUND OF THE INVENTION

Conventional integrated circuit fabrication methods typically include steps to form contact holes (a/k/a via holes) in electrically insulating layers and then fill the contact holes with electrically conductive contact plugs (e.g., metal plugs) using deposition and chemical-mechanical polishing techniques. These conventional methods also include lining the sidewalls of the contact holes with respective barrier layers prior to filling the contact holes with the contact plugs. Each of these barrier layers may include a composite of an underlying glue layer, which directly contacts the sidewalls of a contact hole, and an overlying diffusion barrier layer, which directly contacts the glue layer. A conventional glue layer includes tungsten and a conventional diffusion barrier layer includes tungsten nitride.

Conventional steps to form the contact plugs typically include the chemical-mechanical polishing of a metal layer that has been deposited into the contact holes. Unfortunately, these polishing steps may utilize slurry compositions that can etch-back the glue layers in the contact holes and thereby define voids between the contact plugs and the sidewalls of the contact holes. As will be understood by those skilled in the art, these voids may result in a decrease in the reliability of the integrated circuit devices that utilize the contact plugs as electrical interconnects.

### SUMMARY OF THE INVENTION

Methods of forming integrated circuit devices according to embodiments of the invention include lining an opening in a first electrically insulating layer with a first metal layer and then selectively converting at least a portion of the first metal layer extending adjacent an upper sidewall of the opening into a nitrified first metal layer having a higher concentration of nitrogen therein relative to a portion of the first metal layer extending adjacent a lower sidewall of the opening. A second metal nitride layer is then formed on the nitrified first metal layer. An electrically conductive layer is then deposited on at least a portion of the second metal nitride layer to thereby fill the opening. The electrically conductive layer is then planarized for a sufficient duration to expose the first electrically insulating layer and define an electrically conductive pattern in the opening. The electrically conductive pattern is spaced from the first electrically insulating layer by the second metal nitride layer and the nitrified first metal layer.

According to some of these embodiments, the step of selectively converting at least a portion of the first metal layer into a nitrified first metal layer includes exposing the first metal layer to a nitrogen plasma. This exposing of the first metal layer to a nitrogen plasma may be enhanced by nonuniformly biasing the first metal layer so that a concentration of nitrogen in the nitrified first metal layer is nonuniform. The nitrogen plasma may be established at a pressure in a range from 0.1 Torr to 500 Torr and a temperature in a range from 200° C. to 700° C. According to additional embodiments of the present invention, the step of selectively converting may include heat treating the first metal layer in a nitrogen ambient having a temperature in a range from 200° C. to 950° C.

According to still further embodiments of the present invention, the step of forming the second metal nitride layer includes depositing a second metal nitride layer on the nitrified first metal layer using an atomic layer deposition technique. The second metal nitride layer may be formed to a thickness in a range from 30 Å to 400 Å and the first metal layer may be formed to a thickness in a range from 20 Å to 100 Å. The step of depositing an electrically conductive may include depositing a metal selected from a group consisting of tungsten, copper and aluminum using a chemical vapor deposition technique. Moreover, the step of lining the opening may include lining the opening in the first electrically insulating layer with a first metal layer, using an ionized metal plasma technique or an atomic layer deposition technique.

### BRIEF DESCRIPTION OF THE DRAWINGS

FIG. 1 is a flow diagram of fabrication steps that illustrates methods of forming integrated circuit devices according to embodiments of the present invention.

FIGS. 2A-2H are cross-sectional views of intermediate structures that illustrate methods of forming integrated circuit devices according to embodiments of the present invention.

FIG. 3 is a cross-sectional view of an intermediate structure that illustrates methods of forming integrated circuit devices according to additional embodiments of the present invention.

### DESCRIPTION OF PREFERRED EMBODIMENTS

The present invention now will be described more fully with reference to the accompanying drawings, in which preferred embodiments of the invention are shown. This invention may, however, be embodied in many different forms and should not be construed as being limited to the embodiments set forth herein; rather, these embodiments are provided so that this disclosure will be thorough and complete, and will fully convey the scope of the invention to those skilled in the art. In the drawings, the thickness of layers and regions are exaggerated for clarity. It will also be understood that when a layer is referred to as being “on” another layer or substrate, it can be directly on the other layer or substrate, or intervening layers may also be present. Like numbers refer to like elements throughout.

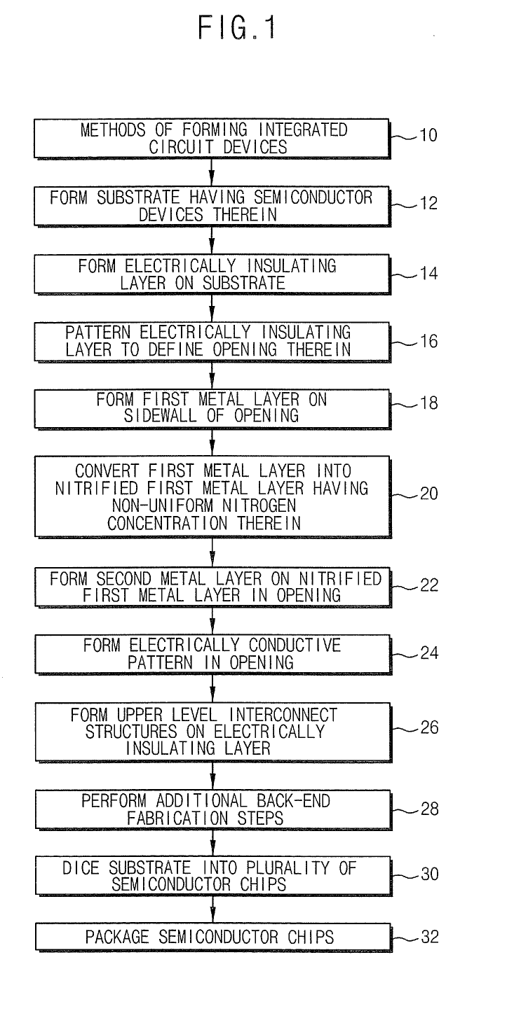

FIG. 1 illustrates methods of forming integrated circuit devices 10 according to embodiments of the present invention. As illustrated by FIG. 1, these methods 10 include forming semiconductor devices (e.g., transistors, sensors, diodes, resistors, logic gates, etc.) in a substrate having semiconductor regions (e.g., N-type regions, P-type regions) therein, Block 12. An electrically insulating layer is formed on the substrate, Block 14. This electrically insulating layer is patterned (e.g., photolithographically patterned) to define at least one opening therein, Block 16. A first metal layer is formed on a sidewall of the opening, Block 18. At least a portion of the first metal layer is then converted into a nitrified first metal layer having a non-uniform nitrogen concentration therein, Block 20. A second metal layer is then formed on the nitrified first metal layer, Block 22. This second metal layer may be a metal nitride layer. The opening is then filled with an electrically conductive pattern, Block 24, which is separated from the sidewall of the opening by the second metal layer and the nitrified first metal layer. Upper level insulating layers and interconnect structures (e.g., wiring patterns and interconnects) may then be formed on the electrically insulating layer, Block 26. Additional back-end fabrication steps are then performed, Block 28, prior to dicing the substrate (e.g., semiconductor wafer) into a plurality of semiconductor chips and packaging the chips, Blocks 30 and 32.

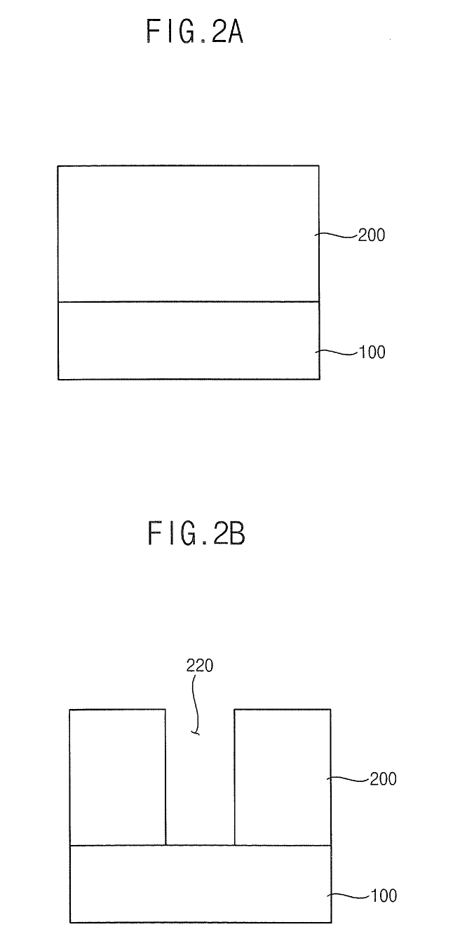

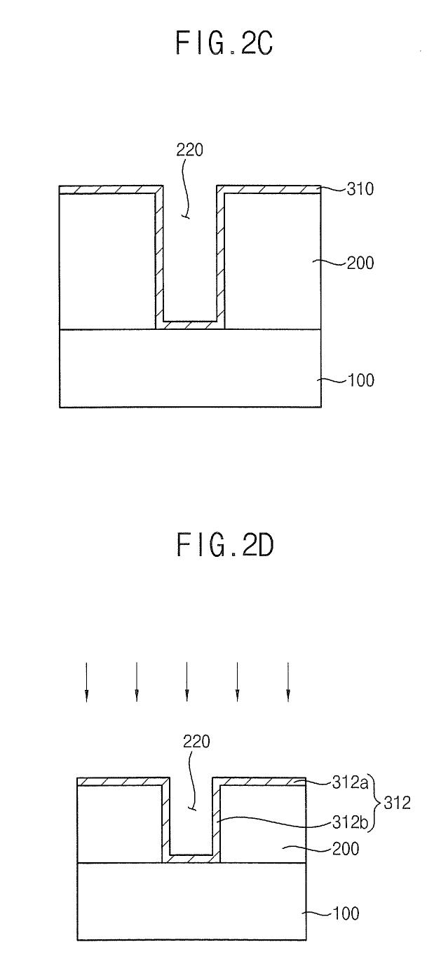

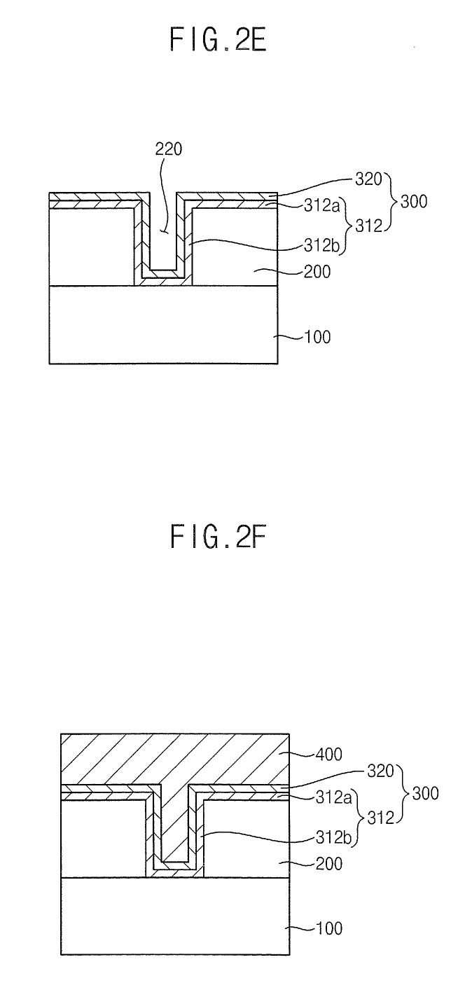

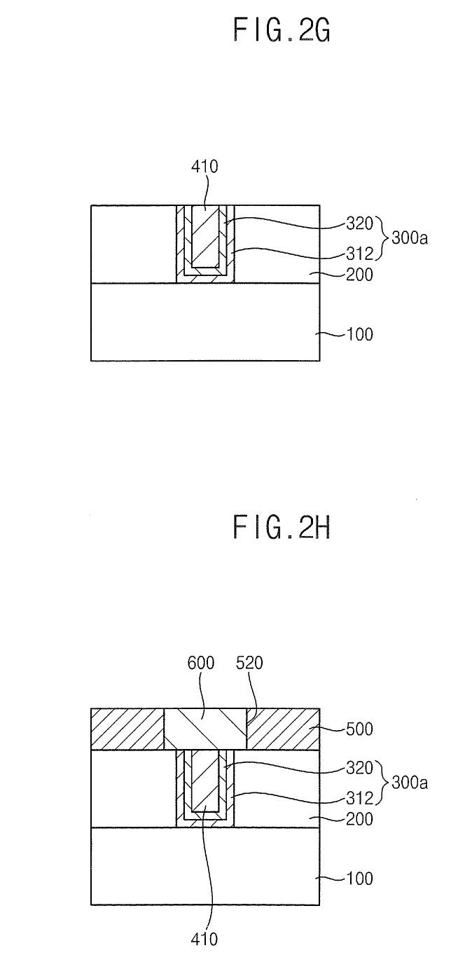

FIGS. 2A-2H illustrate some embodiments of the methods 10 illustrated by FIG. 1. In particular, FIG. 2A illustrates a step to form an electrically insulating layer 200 on a substrate 100. This substrate 100 may be a semiconductor substrate (e.g., silicon wafer) and the electrically insulating layer 200 may include at least one dielectric material. The electrically insulating layer 200 may be formed as a boro-phospho-silicate glass (BPSG) layer, a phospho-silicate glass (PSG) layer, a fluorinated silicate glass (FSG) layer, a plasma-enhanced tetraethyl orthosilicate (PE-TEOS) layer or an undoped silicate glass (USG) layer, for example. The electrically insulating layer 200 may also be formed as a composite of multiple dielectric layers. For example, the electrically insulating layer 200 may be formed to include an underlying first dielectric layer, such as a high density plasma oxide layer or a USG layer, and a overlying second dielectric layer, such as a PE-TEOS layer. A PE-TEOS layer may be formed using a plasma-enhanced chemical vapor deposition (PE-CVD) process that uses tetra-ethoxy silane (Si(OC₂H₅)₄) and 0₂ (or 0₃) as a source gas.

Referring now to FIG. 2B, a patterning step is performed to define an opening 220 (e.g., contact hole) in the electrically insulating layer 200. This opening 220 may be formed using conventional patterning techniques, such as plasma dry etching. The opening 220 may extend through the electrically insulating layer 200 and expose the underlying substrate 100. In alternative embodiments of the invention, the underlying substrate may include an electrically conductive material region (e.g., wiring layer, conductive plug, etc.) having an upper surface that is exposed by the opening 220. A first metal layer 310 is then conformally deposited on the electrically insulating layer 200. This first metal layer 310, which may include tungsten, titanium, cobalt and/or tantalum, for example, may be formed to a thickness in a range from about 20 Å to about 100 Å.

As illustrated by FIG. 2C, this first metal layer 310 extends into and lines a sidewall (and bottom) of the opening 220. This first metal layer 310 may be formed using a ionized metal plasma process or an atomic layer deposition (ALD) process, for example. Alternatively, the first metal layer 310 may be deposited using a pulsed nucleation process or a cyclic chemical vapor deposition (CVD) process. In the event an ALD process is used, the intermediate structure of FIG. 2B may be provided to an ALD process chamber. A reaction material including a source component of the first metal layer is supplied to the process chamber along with a reduction material and a purge gas, while the process chamber is held at a temperature in a range from 250° C. to 550° C. and a pressure in a range from 0.1 to 350 Torr (e.g., 3 Torr). In some embodiments of the invention, the reaction material may include at least one of the following materials: WF6, WCl5, WBr6, WCo6, W(C2H2)6, W(PF3)6, W(allyl)4, (C2H5)WH2, [CH3(C5H4)2]2WH2, (C5H5)W(Co)3(CH3), W(butadiene)3, W(methylvinyl-ketone)3, (C5H5)HW(Co)3 and (C7H8)W(Co)3. The reduction material may include at least one of the following materials: H2, Si2H6, B2H6, PH3 and SiH4. The purge gas may include at least one of the following: He, Ne, Ar, Xe and N₂.

Referring now to FIG. 2D, the first metal layer 310 undergoes a nitridation treatment. This nitridation treatment includes selectively converting at least a portion of the first metal layer 310 extending adjacent an upper sidewall of the opening 220 into a nitrified first metal layer 312. This nitrified metal layer 312 is illustrated as having upper and lower portions 312a and 312b. The upper portion 312a of the nitrified first metal layer 312 has a higher concentration of nitrogen therein relative to the lower portion 312b, which has a lower resistance than the upper portion 312a. According to some embodiments of the invention, the nitridation treatment may include exposing the first metal layer 310 to a nitrogen plasma in a process chamber supplied with N₂, NH₃, N₂+H₂ or combinations thereof. The nitrogen plasma may be accelerated towards the upper portion of the first metal layer 310 by applying a bigger bias to the upper portion of the first metal layer 310 relative to the lower portion of the first metal layer 310. This nitrogen plasma may be established at a power of about 1700 Watts and a bias of about 300 Volts. The nitrogen plasma may be formed at a pressure in a range from about 0.1 Torr to about 10 Torr (e.g., 3 Torr) and at a temperature in a range from about 300° C. to about 700° C. Alternatively, the nitridation treatment may include performing a heat treatment on the first metal layer 310 using a nitrogen gas at a temperature in a range between about 500° C. to about 950° C.

Referring now to FIG. 2E, a second metal nitride layer 320 is then deposited onto the nitrified first metal layer 312, as illustrated, to thereby yield a composite barrier metal layer 300. The second metal nitride layer 320, which may have a thickness in a range from about 30 Å to about 400 Å, may be formed using an atomic layer deposition (ALD) technique, a pulsed nucleation technique or a cyclic chemical vapor deposition (CVD) technique, for example. In the event an ALD technique is used, the intermediate structure of FIG. 2D may be provided to an ALD process chamber. A reaction material including a source component of the first metal layer is supplied to the process chamber along with a second reaction material (e.g., N₂ or NH₃), a reduction material and a purge gas, while the process chamber is held at a temperature in a range from 250° C. to 550° C. and a pressure in a range from 0.1 to 350 Torr (e.g., 3 Torr). In some embodiments of the invention, the reaction material may include at least one of the following materials: WF6, WCl5, WBr6, WCo6, W(C2H2)6, W(PF3)6, W(allyl)4, (C2H5)WH2, [CH3(C5H4)2]2WH2, (C5H5)W(Co)3(CH3), W(butadiene)3, W(methylvinyl-ketone)3, (C5H5)HW(Co)3 and (C7H8)W(Co)3. The reduction material may include at least one of the following materials: H2, Si2H6, B2H6, PH3 and SiH4. The purge gas may include at least one of the following: He, Ne, Ar, Xe and N₂.

After deposition of the second metal nitride layer 320, the opening 220 is filled with an electrically conductive layer. As illustrated by FIG. 2F, an electrically conductive layer 400 may be conformally deposited on the second metal nitride layer 320 to thereby fill the opening 220. According to some embodiments of the invention, a chemical vapor deposition (CVD) technique is used to deposit the electrically conductive layer 400 on the second metal nitride layer 320. The electrically conductive layer 400 may be formed of tungsten, copper or aluminum and alloys thereof, for example. A planarization step may then be performed on the electrically conductive layer 400 to thereby define an electrically conductive pattern 410. In particular, as illustrated by FIG. 2G, a chemical-mechanical polishing (CMP) step may be used to planarize the electrically conductive layer 400 (and underlying metal layers) for sufficient duration to expose the electrically insulating layer 200 and define a barrier metal pattern 300a. During this planarization step, the relatively high concentrations of nitrogen in the upper portion of the nitrified first metal layer 312a and the second metal nitride layer 320 act to inhibit chemical etch-back of the composite barrier metal layer 300a by the slurry composition used during CMP. This inhibition of etch-back also results in a reduction in void formation between the electrically conductive plug 410 and the sidewall of the opening 220.

Referring now to FIG. 2H, an interlayer dielectric layer 500 is deposited on the intermediate structure of FIG. 2G and then an opening 520 is formed in the interlayer dielectric layer 500. As illustrated, this opening 520 is defined to expose an upper surface of the electrically conductive pattern 410. A damascene process may then be performed to define another electrically conductive pattern 600 (e.g., metal wiring pattern) in the opening 520. Alternatively, electro-less and other conventional patterning processes may be used to form the electrically conductive pattern 600. This electrically conductive pattern 600 may be formed as a copper pattern or aluminum pattern, for example.

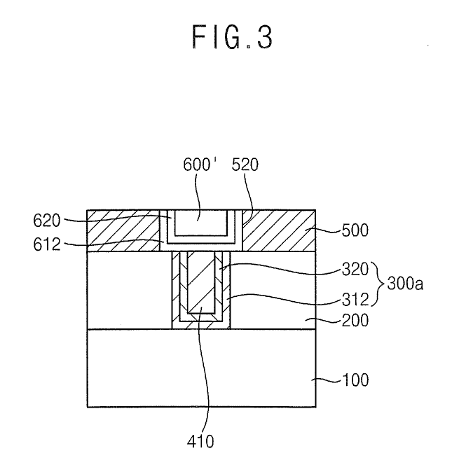

According to alternative embodiments of the present invention, the steps to form the electrically conductive pattern 600 illustrated by FIG. 2H may be preceded by steps to form a composite barrier metal pattern in the opening 520. In particular, as illustrated by FIG. 3, the steps illustrated by FIGS. 2C-2G may be repeated to form a composite barrier metal pattern that extends along a sidewall of the opening 520 and along an upper surface of the underlying electrically conductive pattern 410. This composite barrier metal pattern includes a underlying nitrified metal pattern 612 having a non-uniform concentration of nitrogen therein and a metal nitride pattern 620 extending on the nitrified metal pattern 612. An electrically conductive pattern 600′ also fills the opening. In still further embodiments of the invention, the electrically conductive pattern 600′ may be formed without the underlying electrically conductive pattern 410. Such electrically conductive patterns 600′ may be used in many device applications, including memory device applications. For example, according to some additional embodiments of the invention, the electrically conductive patterns 600′ may be formed as bit line interconnects, column selection lines, and other metal wiring structures.

In the drawings and specification, there have been disclosed typical preferred embodiments of the invention and, although specific terms are employed, they are used in a generic and descriptive sense only and not for purposes of limitation, the scope of the invention being set forth in the following claims.

That which is claimed is:

1. A method of forming an integrated circuit device, comprising:
lining an opening in a first electrically insulating layer with a first metal layer;
selectively converting at least a portion of the first metal layer extending adjacent an upper sidewall of the opening into a nitrified first metal layer having a higher concentration of nitrogen therein relative to a portion of the first metal layer extending adjacent a lower sidewall of the opening;
forming a second metal nitride layer on the nitrified first metal layer;
depositing an electrically conductive layer on at least a portion of the second metal nitride layer to thereby fill the opening; and
planarizing the electrically conductive layer for a sufficient duration to expose the first electrically insulating layer and define an electrically conductive pattern in the opening hole that is spaced from the first electrically insulating layer by the second metal nitride layer and the nitrified first metal layer.

2. The method of claim 1, wherein said selectively converting comprises exposing the first metal layer to a nitrogen plasma.

3. The method of claim 1, wherein said selectively converting comprises exposing the first metal layer to a nitrogen plasma while simultaneously nonuniformly biasing the first metal layer so that a concentration of nitrogen in the nitrified first metal layer is nonuniform.

4. The method of claim 3, wherein the nitrogen plasma is established at a pressure in a range from 0.1 Torr to 500 Torr and a temperature in a range from 200° C. to 700° C.

5. The method of claim 1, wherein said selectively converting comprises heat treating the first metal layer in a nitrogen ambient having a temperature in a range from 200° C. to 950° C.

6. The method of claim 1 wherein forming a second metal nitride layer comprises depositing a second metal nitride layer on the nitrified first metal layer using an atomic layer deposition technique.

7. The method of claim 6, wherein the second metal nitride layer is formed to a thickness in a range from 30 Å to 400 Å; and wherein the first metal layer is formed to a thickness in a range from 20 Å to 100 Å.

8. The method of claim 1, wherein said depositing comprises depositing a metal selected from a group consisting of tungsten, copper and aluminum using a chemical vapor deposition technique.

9. The method of claim 1, wherein said lining comprises lining the opening in the first electrically insulating layer with a first metal layer, using an ionized metal plasma technique.

10. The method of claim 1, wherein said lining comprises lining the opening in the first electrically insulating layer with a first metal layer, using an atomic layer deposition technique.

11. A method of forming an integrated circuit device, comprising:
lining an opening in a first electrically insulating layer with a first metal layer;
selectively converting at least a portion of the first metal layer extending adjacent an upper sidewall of the opening into a nitrified first metal layer; then
depositing a second metal nitride layer on the nitrified first metal layer;
depositing an electrically conductive layer on at least a portion of the second metal nitride layer to thereby fill the opening; and
planarizing the electrically conductive layer for a sufficient duration to expose the first electrically insulating layer and define an electrically conductive pattern in the opening that is spaced from the first electrically insulating layer by the second metal nitride layer and the nitrified first metal layer.

12. The method of claim 11, wherein said selectively converting comprises exposing the first metal layer to a nitrogen plasma.

13. The method of claim 11, wherein said selectively converting comprises exposing the first metal layer to a nitrogen plasma while simultaneously nonuniformly biasing the first metal layer so that a concentration of nitrogen in the nitrified first metal layer is nonuniform.

14. The method of claim 13, wherein the nitrogen plasma is established at a pressure in a range from 0.1 Torr to 500 Torr and a temperature in a range from 200° C. to 700° C.

15. The method of claim 11, wherein said selectively converting comprises heat treating the first metal layer in a nitrogen ambient having a temperature in a range from 200° C. to 950° C.

16. The method of claim 11, wherein depositing a second metal nitride layer comprises depositing a second metal nitride layer on the nitrified first metal layer using an atomic layer deposition technique.

17. The method of claim 16, wherein the second metal nitride layer is formed to a thickness in a range from 30 Å to 400 Å; and wherein the first metal layer is formed to a thickness in a range from 20 Å to 100 Å.

18. The method of claim 11, wherein said depositing an electrically conductive layer comprises depositing a metal selected from a group consisting of tungsten, copper and aluminum using a chemical vapor deposition technique.

19. The method of claim 11, wherein said lining comprises lining the opening in the first electrically insulating layer with a first metal layer, using an ionized metal plasma technique.

20. The method of claim 11, wherein said lining comprises lining the opening in the first electrically insulating layer with a first metal layer, using an atomic layer deposition technique.

21. A method of forming an integrated circuit device, comprising:
forming a first electrically insulating layer on a semiconductor substrate, said first electrically insulating layer having an opening therein;
lining a sidewall of the opening with a nitrified first metal layer having a non-uniform nitrogen concentration therein;
forming an electrically conductive pattern in the opening; and
forming a second metal nitride layer extending between the electrically conductive pattern and the nitrified first metal layer.

22. The method of claim 21, wherein the non-uniform nitrogen concentration in the nitrified first metal layer is greater along an upper portion of the sidewall relative to a lower portion of the sidewall.

23. The method of claim 21, further comprising:
forming upper level interconnect structures on the first electrically insulating layer;
dicing the semiconductor substrate into a plurality of semiconductor chips; and
packaging the plurality of semiconductor chips.

24. The method of claim 21, wherein the non-uniform nitrogen concentration in the nitrified first metal layer yields a nitrified first metal layer having a lower resistivity adjacent a lower portion of the opening and a higher resistivity adjacent an upper portion of the opening.

25. An integrated circuit device, comprising:
a semiconductor substrate;
a first electrically insulating layer on said semiconductor substrate, said first electrically insulating layer having an opening therein;
a nitrified first metal layer having a non-uniform nitrogen concentration therein, lining a sidewall of the opening;
an electrically conductive pattern in the opening; and
a second metal nitride layer extending between said electrically conductive pattern and the nitrified first metal layer.

26. The integrated circuit device of claim 25, wherein the non-uniform nitrogen concentration in said nitrified first metal layer is greater along an upper portion of the sidewall relative to a lower portion of the sidewall.
